(19) United States
(12) Patent Application Publication
(10) Pub. No.: US 2025/0157561 A1
(43) Pub. Date: May 15, 2025

(54) ERROR DETECTION FOR SRAM USED IN A SAFETY-CRITICAL DOMAIN

(71) Applicants: ADVANCED MICRO DEVICES, INC., Santa Clara, CA (US); ATI TECHNOLOGIES ULC, MARKHAM (CA)

(72) Inventors: Uma Sankara Rao Balla, Hyderabad (IN); Carl Kittredge Wakeland, Santa Clara, CA (US); Kaushal Amolak Sanghai, Boxborough, MA (US); Balatripura S. Chavali, Austin, TX (US); Andy Sung, Markham (CA)

(21) Appl. No.: 18/389,056

(22) Filed: Nov. 13, 2023

(51) Int. Cl. G11C 29/42

(52) U.S. Cl. CPC G11C 29/42

(57) ABSTRACT

A system on a chip (SOC) includes a critical domain including components configured to perform critical operations and a non-critical domain including components configured to perform non-critical operations. To help perform such operations, the critical domain and non-critical domain share a static random-access memory (SRAM) that includes a first subset of memory banks assigned to the critical domain and a second subset of memory banks assigned to the non-critical domain. The SOC further includes a memory scrubbing circuitry configured to sequentially check each memory bank of the SRAM for errors. To this end, the memory scrubbing circuitry is configured to check a respective memory bank for errors each time an event trigger occurs by implementing one or more error correction codes.

### BACKGROUND

Some processing systems, such as those in automobiles, are configured to execute programs that control critical operations related to the safety and accessibility of a user. To execute these programs, the processing systems often employ a read-only memory that stores data necessary for the performance of these critical operations. By using a read-only memory, the processing systems help ensure that the data necessary for the performance of these critical operations is not overwritten or altered. However, various conditions experienced by the processing system, such as cosmic rays, are able to corrupt or alter the data stored in the read-only memory. Such corruption of the data introduces errors in the performance of the critical operations, decreasing the reliability of these critical operations and endangering the user.

### BRIEF DESCRIPTION OF THE DRAWINGS

The present disclosure may be better understood, and its numerous features and advantages are made apparent to those skilled in the art by referencing the accompanying drawings. The use of the same reference symbols in different drawings indicates similar or identical items.

FIG. 1 is a block diagram of a processing system having a static random-access memory (SRAM) shared between a critical domain and a non-critical domain, in accordance with some embodiments.

FIG. 2 is a block diagram of a memory scrubbing circuitry configured for SRAM scrubbing, in accordance with some embodiments.

FIGS. 3 and 4 together present a sequence diagram of an example operation for SRAM scrubbing, in accordance with some embodiments.

FIG. 5 is a flow diagram of an example method for SRAM scrubbing, in accordance with some embodiments.

### DETAILED DESCRIPTION

Systems and techniques disclosed herein include a processing system, such as an audio processing system implemented in vehicles, that is partitioned into a critical domain and a non-critical domain. The critical domain includes components such as controllers responsible for critical functions, for example, generating alerts, handling remote applications, and handling emergency calls. The non-critical domain includes components such as a central processing unit (CPU), interconnects, and external input/output (I/O) devices configured to perform non-critical audio functions, for example, internet radio processing and non-critical communications. In some implementations, as an example, the critical and non-critical domains are partitioned regions of the processing system based on market, application, use case, or any combination thereof. The components of both the critical and non-critical domains share a static random access memory (SRAM) configured to store instructions, boot images, results, and the like necessary for, helpful for, or aiding in the performance of critical and non-critical functions.

To help ensure the reliability of the critical functions performed by the components of the critical domain, the processing system is configured to divide the memory banks of the SRAM such that a first subset of the memory banks is assigned to the critical domain as critical memory banks and a second subset of the memory banks is assigned to the non-critical domain as non-critical memory banks. As an example, the processing system includes a secure processor that assigns a first subset of the memory banks to the critical domain and a second subset of the memory banks to the non-critical domain by writing to a secure register. Such critical memory banks, for example, include store instructions, boot images, results, and the like necessary for, helpful for, or aiding in the performance of critical functions. Further, the processing system includes a memory arbiter having circuitry configured to control access to the critical memory banks and non-critical memory banks. As an example, the memory arbiter is configured to allow only components within the critical domain of the processing system to access critical memory banks and deny components within the non-critical domain access to critical memory banks. Additionally, the memory arbiter is configured to designate data stored in the critical memory banks as read-only such that neither components in the critical domain nor components in the non-critical domain have write access to critical memory banks storing data. In this way, the processing system helps ensure that the data stored in the critical memory banks is not altered or overwritten, helping the critical functions to function properly.

However, certain conditions external to the processing system are likely to cause data written to the memory banks of the SRAM to become corrupted, which introduces errors in the performance of the critical functions. As an example, radiation due to cosmic rays or alpha particle emissions increases the likelihood of bitflips for data written to one or more memory banks of the SRAM. To this end, systems and techniques disclosed herein are directed to performing error correction on the memory banks of the SRAM. For example, the processing system includes one or more finite state machines configured to sequentially check each memory bank of the SRAM for one or more single-bit memory errors, multi-bit memory errors, or both. To sequentially check each memory bank of the SRAM, for example, a finite state machine first waits for an event trigger to occur. These event triggers include a pre-determined amount of time elapsing, an event (e.g., boot-up, power down) occurring, a condition being detected within the processing system, or the like. Once the event trigger has occurred, the finite state machine begins to check the data and tags of a first memory bank of the SRAM for one or more single-bit memory errors, multi-bit memory errors, or both. To this end, the finite state machine implements one or more error correction codes (ECCs) configured to check for and correct single-bit memory errors, multi-bit memory errors, or both. Based on detecting one or more single-bit memory errors or multi-bit memory errors in the data and tags of the first memory bank, the finite state machine corrects the data and tags based on the implemented ECCs and writes the corrected data and tags to the memory bank, even if, for example, the data in the memory bank was designated as read-only. If the finite state machine detects a memory error that cannot be corrected by an implemented ECC, the finite state machine issues one or more interrupts so as to cause a reboot of the critical domain, non-critical domain, or both.

After checking the data and tags of the first memory bank, the finite state machine again waits for the event trigger to occur. Once the event trigger occurs again, the finite state machine checks the next sequential memory bank in the SRAM for memory errors. As an example, the finite state machine checks the next sequential memory bank as indicated by memory addresses associated with the SRAM. The finite state machine then continues until each memory bank of the SRAM has been checked for memory errors. In this way, the finite state machine is able to detect and correct one or more memory errors within the data stored in the SRAM, helping to reduce errors in the performance of critical functions and improving their reliability. Additionally, to address memory errors (e.g., memory faults) that occur in the processing system, the finite state machine is configured to receive one or more redirect requests. Such a redirect request, for example, indicates that a memory error (e.g., memory fault) has occurred in one or more memory banks of the SRAM. Based on receiving a redirect request, the finite state machine is configured to check for memory errors in the memory banks indicated in the redirect request. For example, rather than move to a next sequential memory bank after checking a first memory bank, the finite state machine begins checking the memory bank indicated in a redirect request after the event trigger occurs. As such, the finite state machine is configured to address memory errors as they occur, again helping to reduce errors in the performance of critical functions and improving the reliability of the critical functions.

As used herein, “circuitry”, in at least some embodiments, is any one of, or a combination of, a hardcoded circuit (e.g., a corresponding portion of an application specific integrated circuit (ASIC) or a set of logic gates, storage elements, and other components selected and arranged to execute the ascribed operations), a programmable circuit (e.g., a corresponding portion of a field programmable gate array (FPGA) or programmable logic device (PLD)), or one or more processors executing software instructions that cause the one or more processors to implement the ascribed actions. In some embodiments, the circuitry for a particular element is selected, arranged, and configured by one or more computer-implemented design tools. For example, in some embodiments the sequence of operations for a particular element is defined in a specified computer language, such as a register transfer language, and a computer-implemented design tool selects, configures, and arranges the circuitry based on the defined sequence of operations.

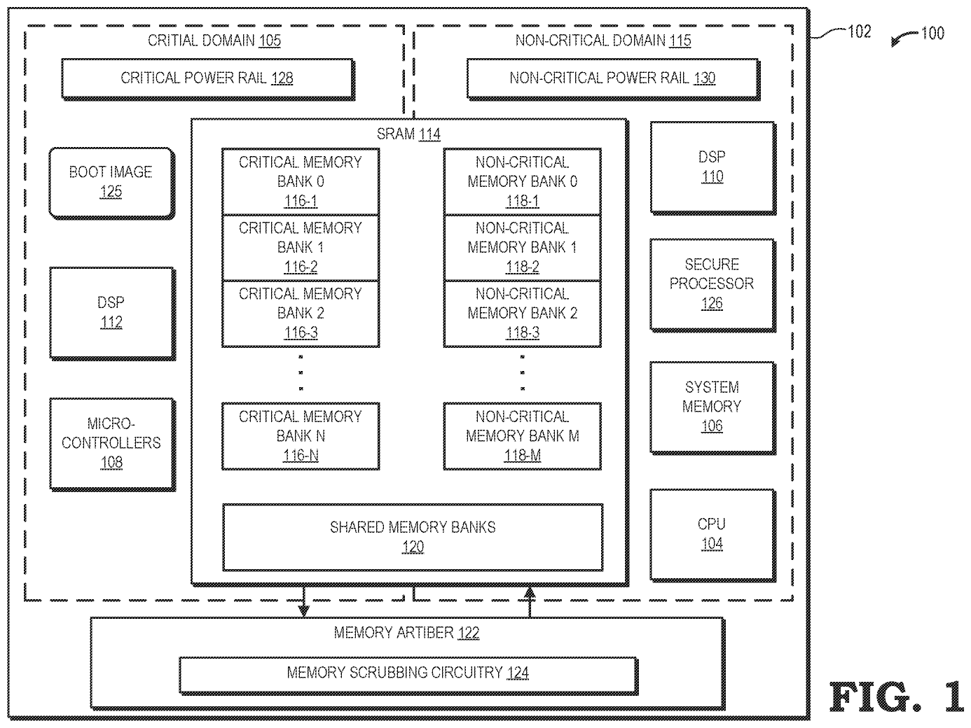

Referring now to FIG. 1, a processing system 100 including a SRAM 114 shared between a critical domain 105 and a non-critical domain 115 of a system-on-a-chip (SOC) 102 is presented, in accordance with some embodiments. In embodiments, processing system 100 is generally configured to execute sets of instructions from one or more applications so as to carry out certain tasks for an electronic device. Such tasks, for example, include controlling one or more aspects of the operation of the electronic device, displaying information to a user, communicating with other electronic devices, or any combination thereof, to name a few. Accordingly, in some embodiments, the processing system 100 is employed in one of a number of types of electronic device, for example, a desktop computer, laptop computer, server, game console, tablet, smartphone, and the like. According to embodiments, SOC 102 is configured for one or more applications in an automobile, for example, automotive infotainment system applications. In some embodiments, as an example, SOC 102 includes an audio processor for automobile applications (e.g., automotive infotainment system applications).

In embodiments, the processing system 100 is configured to execute instructions associated with non-critical functions and critical functions. Non-critical functions include, as an example, communication functions (e.g., Bluetooth, Wi-Fi), internet radio functions, radio tuner functions, non-emergency telephony functions, audio processing functions, or any combination thereof, to name a few. Further, critical functions include, for example, alarm (e.g., tamper alarm, intrusion alarm) functions; alert functions (e.g., chimes, audio cues) associated with driving, turn signals, and open doors; pedestrian warning sound functions; emergency alert functions; remote functions (e.g., remote honking, remote locking, remote unlocking); emergency telephony functions; and glass alarm functions (e.g., glass break sensing and alarms).

To perform instructions for one or more non-critical functions, the processing system 100 includes non-critical domain 115 powered by, for example, non-critical power rail 130. Non-critical domain 115 includes, for example, central processing unit (CPU) 104, system memory 106, one or more digital signal processors (DSPs) 110, and secure processor 126. According to embodiments, CPU 104, system memory 106, DSPs 110, secure processor 126, or any combination thereof of non-critical domain 115 are powered by non-critical power rail 130 configured to provide one or more voltages, currents, or both. In embodiments, CPU 104 includes one or more instruction pipelines configured to fetch instructions, decode the instructions into corresponding operations, dispatch the operations to one or more execution units, execute the operations, and retire the operations. While executing these instructions, in some embodiments, CPU 104 generates one or more operations and provides one or more commands, data, or both indicating the operations to the DSPs 110 for performance. As an example, CPU 104 generates audio operations and other operations associated with the audio display of information and provides commands, data, or both indicating the audio operations and other operations associated with the audio display of information to DSPs 110. In embodiments, one or more DSPs 110 are to receive the commands and data associated with audio processing operations from the CPU 104 or a host operating system (OS) (not shown). These DSPs 110, for example, include one or more processors configured to implement digital signal algorithms and techniques for, as an example, audio processing. Such algorithms include, for example, finite impulse response (FIR) filtering algorithms and the like. In general, a DSP 110 will perform such algorithms more efficiently (e.g., faster, using less power or other resources) than CPU 104 or other processor in a computing system. Accordingly, in some implementations, CPU 104 or a host OS transfers data and commands to DSPs 110 to perform calculations for such algorithms. Further CPU 104 of a host OS retrieves the results after DSPs 110 have completed the calculations.

According to embodiments, CPU 104 and DSPs 110 are coupled to system memory 106. In embodiments, CPU 104 and DSPs 110 are configured to execute instructions for applications stored as program code in system memory 106. Further, CPU 104 and DSPs 110 are configured to store information in system memory 106 such as the results of executed instructions. In various embodiments, system memory 106 stores processing logic instructions, constant values, variable values during execution of portions of applications or other processing logic, or other desired information. During execution, applications, operating system functions, processing logic commands, and system software reside in system memory 106. Control logic commands that are fundamental to the operating system generally reside in system memory 106 during execution. In some embodiments, other software commands (e.g., a device driver) also reside in system memory 106 during execution of the CPU 104. For example, system memory 106 stores a plurality of previously generated audio data (not shown) received from DSPs 110. According to some embodiments, system memory 106 is implemented as a dynamic random access memory (DRAM), and in some embodiments, system memory 106 is implemented using other types of memory including SRAM, non-volatile RAM, and the like. Some embodiments of the processing system 100 include an input/output (I/O) engine (not shown) for handling input or output operations associated with an audio system (not shown), as well as other elements of the processing system 100 such as microphones, speakers, tuners, controllers, and the like.

To perform instructions for one or more critical functions, the processing system 100 includes critical domain 105 powered by, for example, critical power rail 128. Critical domain 105 includes, for example, one or more microcontrollers 108 and one or more DSPs 112. In embodiments, microcontrollers 108 and DSPs 112 of critical domain 105 are powered by critical power rail 128 configured to provide one or more voltages, currents, or both. According to embodiments, critical power rail 128 is separate and distinct from non-critical power rail 130 such that critical power rail 128 provides one or more first voltages, currents, or both to critical 105 without influence from the non-critical power rail 130. In this way, components of critical domain 105 will continue to function even if a loss of power occurs at the non-critical power rail 130. In embodiments, microcontrollers 108 include one or more instruction pipelines for fetching instructions, decoding the instructions into corresponding operations, dispatching the operations to one or more execution units, executing the operations, and retiring the operations. According to some embodiments, while executing such instructions, one or more microcontrollers 108 generate one or more operations and provide one or more commands, data, or both indicating the operations to the DSPs 112 for performance. For example, one or more microcontrollers 108 generate operations associated with alarm functions, alert functions, pedestrian warning sound functions, emergency alert functions, remote functions, emergency telephony functions, glass alarm functions, or any combination thereof and provide information associated with these commands to DSPs 112.

According to embodiments, SRAM 114 is shared between critical domain 105 and non-critical domain 115 such that one or more memory banks of SRAM 114 are assigned to critical domain 105, one or more memory banks of SRAM 114 are assigned to non-critical domain 115, one or more memory banks are assigned to both critical domain 105 and non-critical domain 115, or any combination thereof. To this end, in embodiments, secure processor 126 is configured to allocate one or more memory banks to critical domain 105, non-critical domain 115, or both. For example, in some embodiments, secure processor 126, at a cold-boot time, is configured to allocate a first subset of memory banks to critical domain 105 and a second subset of memory banks to non-critical domain 115 by writing to a secure register (not shown for clarity). Secure processor 126 then blocks subsequent write access to the secure register, for example, to prevent the memory banks from being reallocated. Referring to the example embodiment presented in FIG. 1, secure processor 126 is configured to assign a first number of memory banks to critical domain 105, represented in FIG. 1 as critical memory banks 116, a second number of memory banks to non-critical domain 115, represented in FIG. 1 as non-critical memory banks 118, and a third number of memory banks to both critical domain 105 and non-critical domain 115, represented in FIG. 1 as shared memory banks 120. In embodiments, shared memory banks 120 allow data to be shared between critical domain 105 and non-critical domain 115. As an example, audio data streams and messages are communicated between the critical domain 105 and the non-critical domain 115 via one or more shared memory banks 120. Though FIG. 1 presents critical domain 105 as being assigned four critical memory banks (116-1, 116-2, 116-3, 116-N) representing an N number of memory banks, in other embodiments, critical domain 105 may be assigned any number of critical memory banks 116. Similarly, Though FIG. 1 presents non-critical domain 115 as being assigned four non-critical memory banks (118-1, 118-2, 118-3, 118-M) representing an M number of memory banks, in other embodiments, non-critical domain 115 may be assigned any number of critical memory banks 118. Further, though in the example embodiment of FIG. 1 critical domain 105 and non-critical domain 115 are depicted as being assigned the same number of memory banks of SRAM 114, in other embodiments, critical domain 105 and non-critical domain 115 may be assigned different numbers of memory banks of SRAM 114. In some example embodiments, each memory bank of SRAM 114 includes 128 kB.

To help enable one or more microcontrollers 108 of critical domain 105 to boot independently from CPU 104 and other components of non-critical domain 115, boot image 125 for critical domain 105 is stored within the SOC 102 such that boot image 125 is retained independent of the power state of non-critical domain 115 (e.g., independent of non-critical power rail 130). According to embodiments, the boot process for one or more microcontrollers 108 does not depend on non-critical domain 115. To this end, in embodiments, secure processor 126 is configured to designate one or more critical memory banks 116 to store boot image 125 received, as an example, from an external boot source. In embodiments, such an external boot source is a read-only memory (ROM) or other off-SOC storage device such as a flash drive or non-volatile memory. According to some embodiments, secure processor 126, during a cold boot process, is configured to load boot image 125 from a boot source onto SOC 102 and validates boot image 125 by, for example, verifying a cryptographic signature, comparing a hash function, or employing a secure boot mechanism. After validating boot image 125, secure processor 126 transfers boot image 125 to one or more designated critical memory banks 116 of SRAM 114. Further, in some embodiments, secure processor 126 is configured to lock boot image 125 at the one or more designated critical memory banks 116 to prevent subsequent write access to boot image 125. For example, secure processor 126 sets a read-only or a write-once bit for boot image 125. To help ensure the boot process for microcontroller 108 in the event that critical power rail 128, non-critical power rail 130, or both fail, SRAM 114 is powered by a backup power rail (not pictured for clarity) configured to provide one or more voltages, current, or both independent of critical power rail 128 and non-critical power rail 130. In this way, SRAM 114 is configured to retain data in critical memory banks 116, non-critical memory banks 118, shared memory banks 120, or any combination thereof even if critical power rail 128, non-critical power rail 130, or both fail.

Additionally, in embodiments, microcontrollers 108, DSPs 112, or both are configured to read and write critical data to one or more critical memory banks 116, shared memory banks 120, or both. Such critical data, for example, includes data (e.g., instructions, register files, variables, constants, scalar parameters, vector parameters) necessary for, aiding in, or helpful for performing one or more critical operations, data (e.g., results) resulting from the performance of one or more critical operations, or both. Further, CPU 104, DSPs 110, or both are configured to read and write non-critical data to one or more non-critical memory banks 118, shared memory banks 120, or both. Non-critical data, for example, includes data (e.g., instructions, register files, variables, constants, scalar parameters, vector parameters) necessary for, aiding in, or helpful for performing one or more non-critical operations, data (e.g., results) resulting from the performance of one or more non-critical operations, or both.

According to embodiments, SOC 102 includes memory arbiter 122 configured to control access (e.g., read access, write access, fetch access) to each critical memory bank 116, non-critical memory bank 118, and shared memory bank 120 of SRAM 114. For example, memory arbiter 122 includes circuitry configured to grant or deny access to each critical memory bank 116, non-critical memory bank 118, and shared memory bank 120 by CPU 104, one or more DSPs 110, one or more microcontrollers 108, one or more DSPs 112, or any combination thereof. As an example, in embodiments, memory arbiter 122 is configured to allow read access, write access, or both to one or more critical memory banks 116, non-critical memory banks 118, or both to a component (e.g., CPU 104, microcontroller 108, DSP 110, DSP 112) based on whether the component is associated with critical domain 105 or non-critical domain 115. For example, in some embodiments, memory arbiter 122 is configured to deny access to critical memory banks 116 by components associated with (e.g., within) non-critical domain 115. In this way, memory arbiter 122 ensures that components within non-critical domain 115 do not alter data stored in the critical memory banks 116, improving the reliability of critical domain 105. Further, to help ensure that data within critical memory banks 116 is not altered, in some embodiments, memory arbiter 122 is configured to lock the data written in a critical memory bank 116 so as to prevent subsequent write access to the written data by any component (e.g., agent) of processing system 100 other than memory scrubbing circuitry 124. As an example, in response to data being written to a first critical memory bank 0 116-1, memory arbiter 122 sets a read-only or a write-once bit for the written data or the entirety of the first critical memory bank 0 116-1. Due to the written data being locked, memory arbiter 122 then denies write requests coming from components within both critical domain 105 and non-critical domain 115, helping ensure that the written data is not altered or overwritten, further improving the reliability of critical domain 105.

However, certain conditions external to SOC 102 increase the likelihood that data written to one or more memory banks of SRAM 114 becomes corrupted and introduces errors in the written data (e.g., memory errors). As an example, radiation due to cosmic rays or alpha particle emissions increases the likelihood of bitflips for data written to one or more memory banks of SRAM 114 and decreases the reliability of critical domain 105. To help correct these memory errors in the written data, SOC 102 includes memory scrubbing circuitry 124 included in or otherwise connected to memory arbiter 122. Memory scrubbing circuitry 124, for example, is configured to detect and correct single-bit memory errors, multi-bit memory errors, or both within the data written to memory banks of SRAM 114 (e.g., critical memory banks 116, non-critical memory banks 118, shared memory banks 120) by employing one or more error correction codes (ECCs). As an example, memory scrubbing circuitry 124 implements a checksum, cyclic redundancy check (CRC), block ECC (Hamming ECC, Reed-Solomon coding), or any combination thereof to detect and correct single-bit memory errors, multi-bit memory errors, or both in data written to memory banks of SRAM 114. In embodiments, to detect errors in a first memory bank of SRAM 114, memory scrubbing circuitry 124 first reads the data from the memory bank and checks for one or more single-bit memory errors, multi-bit memory errors, or both. Based on detecting a single-bit memory error or multi-bit memory errors, memory scrubbing circuitry 124 corrects the memory errors based on the ECC implemented and writes the corrected data back into the memory bank of the SRAM 114. According to embodiments, memory arbiter 122 is configured to grant memory scrubbing circuitry 124 write access to critical memory banks 116, non-critical memory banks 118, and shared memory banks 120 even if the data has been locked (e.g., even if write access has been blocked for components of critical domain 105 and non-critical domain 115). That is to say, memory arbiter 122 grants memory scrubbing circuitry 124 write access to critical memory banks 116, non-critical memory banks 118, and shared memory banks 120 even if a read-only or a write-once bit has been set for the data in a memory bank or the memory bank as a whole.

According to embodiments, memory scrubbing circuitry 124 is configured to check each memory bank of SRAM 114 sequentially. As an example, in embodiments, based on an event trigger occurring, memory scrubbing circuitry 124 is configured to check for and correct single-bit memory errors, multi-bit memory errors, or both in a first memory bank of SRAM 114. Such an event trigger, for example, includes a pre-determined amount of time elapsing, an event (e.g., boot-up, power down) occurring in critical domain 105 or non-critical domain 115, a condition (e.g., predetermined temperature, predetermined voltage) being detected at SOC 102, or any combination thereof. As an example, in embodiments, an event trigger includes a predetermined amount of time such that memory scrubbing circuitry 124 is configured to check for and correct single-bit memory errors, multi-bit memory errors, or both in a first memory bank of SRAM 114 based on the predetermined amount of time elapsing. After checking each bit of the data in the first memory bank of the SRAM 114, memory scrubbing circuitry 124 is configured to check for and correct single-bit memory errors, multi-bit memory errors, or both in a second memory bank of SRAM 114 based on a second event trigger occurring. As an example, memory scrubbing circuitry 124 is configured to check for and correct single-bit memory errors, multi-bit memory errors, or both in a second memory bank of SRAM 114 based on the predetermined amount of time again elapsing. In embodiments, the second memory bank of SRAM 114 that is checked for memory errors is the next sequential memory bank within SRAM 114 (e.g., as indicated by one or more memory addresses associated with SRAM 114). In this way, memory scrubbing circuitry 124 is configured to sequentially check each memory bank of SRAM 114 based on event triggers occurring. As an example, memory scrubbing circuitry 124 is configured to sequentially check each memory bank of SRAM 114 based on predetermined amounts of time elapsing.

In embodiments, memory scrubbing circuitry 124 is configured to generate one or more interrupts based on detecting one or more single-bit memory errors, multi-bit memory errors, or both in a memory bank. As an example, based on detecting a single-bit memory error or multi-bit memory error that cannot be corrected by the ECC implemented by memory scrubbing circuitry 124, memory scrubbing circuitry 124 generates one or more interrupts. Such interrupts, for example, indicate an uncorrected memory error has been detected in a memory bank of SRAM 114 and the domain (e.g., critical domain 105, non-critical domain 115) associated with the memory bank (e.g., domain to which the memory bank was assigned). After generating the interrupt, memory scrubbing circuitry 124 then provides the interrupt to CPU 104, one or more microcontrollers 108, secure processor 126, or any combination thereof based on, for example, the domain indicated in the interrupt. In response to receiving such an interrupt, CPU 104, one or more microcontrollers 108, secure processor 126, or any combination thereof are configured to reboot at least a portion of the domain indicated in the interrupt. Additionally, in embodiments, after a predetermined amount of time has elapsed (e.g., hours, days, weeks, months) and when processing system 100 is dormant (e.g., off, in rest mode), CPU 104, one or more microcontrollers 108, secure processor 126, or any combination thereof are configured to reboot processing system 100 to reinitialize the critical memory banks 116.

According to embodiments, memory scrubbing circuitry 124 is configured to receive one or more redirect requests from CPU 104, one or more microcontrollers 108, secure processor 126, or any combination thereof. Such redirect requests, for example, indicate that a memory error (e.g., memory fault) has occurred in a memory bank of SRAM 114. As an example, a redirect request indicates a memory error has occurred in a certain memory bank. Based on receiving the redirect request, memory scrubbing circuitry 124 checks the memory bank indicated in the redirect request for one or more single-bit memory errors, multi-bit memory errors, or both by implementing one or more ECCs. As an example, based on receiving the redirect request, memory scrubbing circuitry 124 pauses checking a current memory bank for memory errors and begins checking the memory bank indicated in the redirect request. As another example, based on receiving the redirect request, memory scrubbing circuitry 124 checks the memory bank indicated in the redirect request for memory errors rather than the next sequential memory bank of SRAM 114 after completing an error check for a current memory bank.

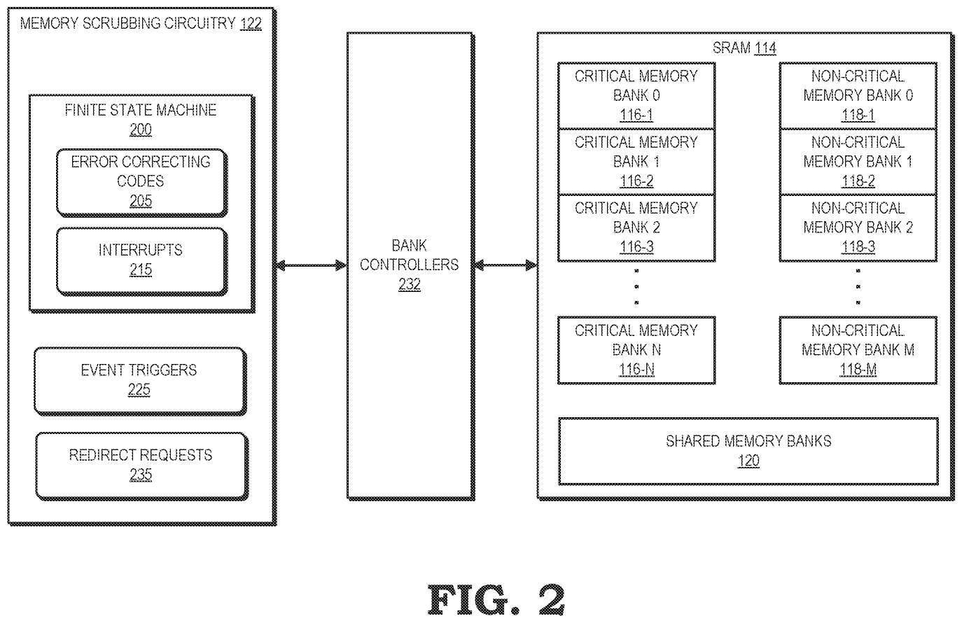

Referring now to FIG. 2, a finite state machine 200 configured for SRAM scrubbing is presented, in accordance with some embodiments. In embodiments, finite state machine 200 is implemented within or otherwise connected to memory scrubbing circuitry 124 in processing system 100. According to some embodiments, finite state machine 200 includes a hardware-based finite state machine 200 configured for SRAM scrubbing. In embodiments, finite state machine 200 is configured to check each memory bank of SRAM 114 for one or more single-bit memory errors, multi-bit memory errors, or both. As an example, finite state machine 200 is configured to check and correct data stored in each critical memory bank 116, non-critical memory bank 118, and each shared memory bank 120 for one or more single-bit memory errors, multi-bit memory errors, or both. To detect and correct such memory errors within the memory banks of SRAM 114, finite state machine 200 is configured to implement one or more ECCs 205. These ECCs, for example, include a checksum, CRC, block ECC (Hamming ECC, Reed-Solomon coding), or any combination thereof configured to check for and correct single-bit memory errors, multi-bit memory errors, or both within data.

According to some embodiments, finite state machine 200 is configured to check the data in a first memory bank (e.g., critical memory bank 0 116-1) for memory errors in response to an event trigger 225 occurring. An event trigger 225, for example, includes a pre-determined amount of time elapsing (e.g., a predetermined time interval elapsing), an event (e.g., boot-up, power down) occurring in critical domain 105 or non-critical domain 115, a condition (e.g., predetermined temperature, predetermined voltage) being detected at SOC 102, or any combination thereof. As an example, based on a predetermined time interval elapsing, finite state machine 200 is configured to check data in a first memory bank of SRAM 114 for memory errors. To check data in the first memory bank, finite state machine 200 first generates a read request indicating data in the first memory bank. Finite state machine 200 then sends the read request (e.g., via memory arbiter 122) to a bank controller 232 associated with the first memory bank. A bank controller 232, for example, includes circuitry configured to handle access requests for one or more associated memory banks of SRAM 114. For example, a first bank controller includes circuitry configured to handle access requests for the first memory bank of SRAM 114. As an example, a bank controller 232 is configured to read-out data from an associated memory bank indicated in a read request, write data to an associated memory bank as indicated in a write request, or both.

Based on receiving the read request from finite state machine 200, the bank controller 232 associated with the memory bank indicated in the read request begins to read out data from the indicated memory bank and provides the data to finite state machine 200. In response to receiving the read-out data from a bank controller 232, finite state machine 200 implements one or more ECCs 205 so as to detect one or more single-bit memory errors, multi-bit memory errors, or both in the read-out data. Based on one or more ECCs 205 detecting a single-bit memory error or multi-bit memory error, the ECCs correct the detected single-bit memory error or multi-bit memory error within the read-out data to produce correct data. Finite state machine 200 then generates a write request indicating the memory bank from which the data was read out and indicating the corrected data. Memory arbiter 122, memory scrubbing circuitry 124, or both then provide the write request to the bank controller associated with the memory bank. The bank controller 232 then writes the corrected data to the memory bank.

In response to detecting a single-bit memory error or multi-bit memory error that cannot be corrected by the ECCs 205 implemented by finite state machine 200, finite state machine 200 generates one or more interrupts 215. Such interrupts 215, for example, include data indicating an uncorrected memory error has been detected in a memory bank of SRAM 114 and the domain (e.g., critical domain 105, non-critical domain 115) associated with the memory bank (e.g., domain to which the memory bank was assigned). After finite state machine 200 generates an interrupt 215, memory arbiter 122, memory scrubbing circuitry 124, the interrupt to CPU 104, one or more microcontrollers 108, secure processor 126, or any combination thereof based on, for example, the domain indicated in the interrupt.

After checking all the data in a first memory bank of SRAM 114 for one or more memory errors, finite state machine 200 is configured to begin checking the data in a second memory bank (e.g., critical memory bank 1 116-2) based on a second event trigger 225 occurring. In some embodiments, the second event trigger 225 is the same as the first event, while in other embodiments, the second event trigger 225 is different from the first trigger event 225. For example, based on the second trigger event 225 occurring, finite state machine 200 begins checking a second memory bank of SRAM 114 that is the next sequential memory bank within SRAM 114 as indicated by one or more memory addresses (e.g., virtual memory addresses, physical memory addresses) associated with SRAM 114. As an example, after checking all the data in a first memory bank of SRAM 114 for one or more memory errors, finite state machine 200 waits a predetermined amount of time before (e.g., as indicated by an event trigger 225) before checking data in a next sequential memory bank of SRAM 114 for one or more memory errors. In this way, finite state machine 200 is configured to sequentially check each memory bank of SRAM 114 for one or more errors.

According to some embodiments, memory scrubbing circuitry 124 includes two or more finite state machines 200 each configured to check respective memory banks of SRAM 114 for single-bit memory errors, multi-bit memory errors, or both by implementing one or more ECCs 205. In embodiments, two or more finite state machines 200 of memory scrubbing circuitry 124 are configured to concurrently check respective memory banks of SRAM 114 for single-bit memory errors, multi-bit memory errors, or both. As an example, a first finite state machine 200 is configured to check a first memory bank of SRAM 114 for memory errors concurrently with a second finite state machine 200 checking a second memory bank of SRAM 114 for memory errors. In embodiments, a first finite state machine 200 of memory scrubbing circuitry 124 sequentially checks a first portion (e.g., a first subset of memory banks) of SRAM 114 for memory errors concurrently with a second finite state machine 200 of memory scrubbing circuitry 124 sequentially checking a second portion (e.g., a second subset of memory banks) of SRAM 114 for errors.

In embodiments, finite state machine 200 is configured to receive one or more redirect requests 235 from, for example, CPU 104, one or more microcontrollers 108, secure processor 126, or any combination thereof. A redirect request 235, as an example, includes data indicating that a memory error (e.g., memory fault) has occurred in a certain memory bank of SRAM 114. To this end, in embodiments, a redirect request 235 includes data indicating a memory error has occurred and data identifying the memory bank associated with the memory error. According to embodiments, based on receiving a redirect request 235, finite state machine 200 is configured to check data in the memory bank identified in the redirect request 235 for one or more memory errors. In some embodiments, in response to receiving a redirect request 235, finite state machine 200 pauses checking the data in a current memory bank for memory errors and begins checking data in the memory bank identified in the redirect request 235. For example, based on receiving a redirect request 235, finite state machine 200 suspends a read request sent to a first memory bank and generates a second read request to a second memory bank identified in the redirect request 235. Finite state machine 200 then checks the data in the second memory bank for one or more memory errors. In other embodiments, in response to receiving a redirect request 235, finite state machine 200 first completes checking the data in a first memory bank. After all the data in the first memory bank have been checked, finite state machine 200 generates a read request indicating a second memory bank indicated in the redirect request 235 rather than a next sequential memory bank. Finite state machine 200 then checks the data in the second memory bank for one or more memory errors.

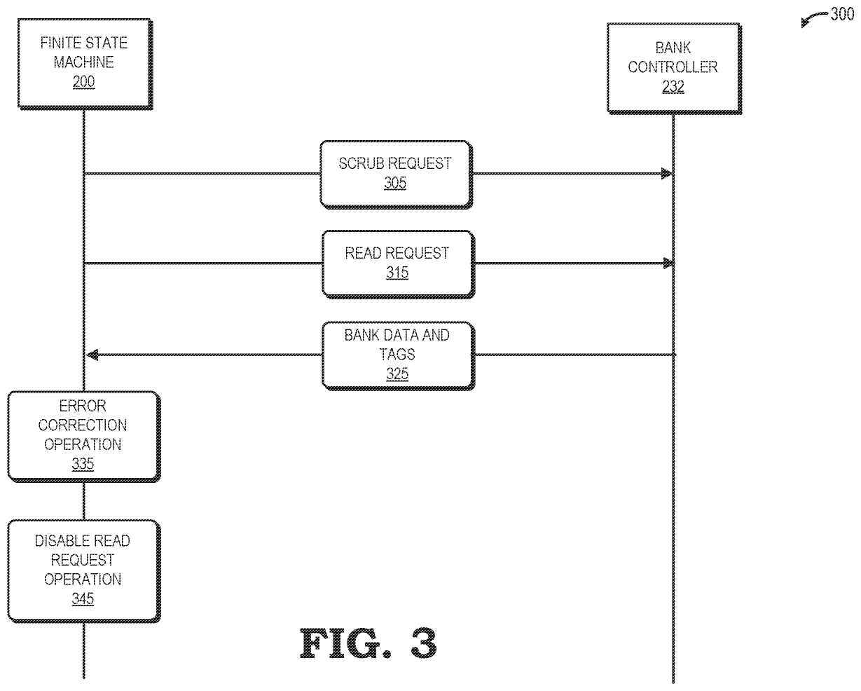

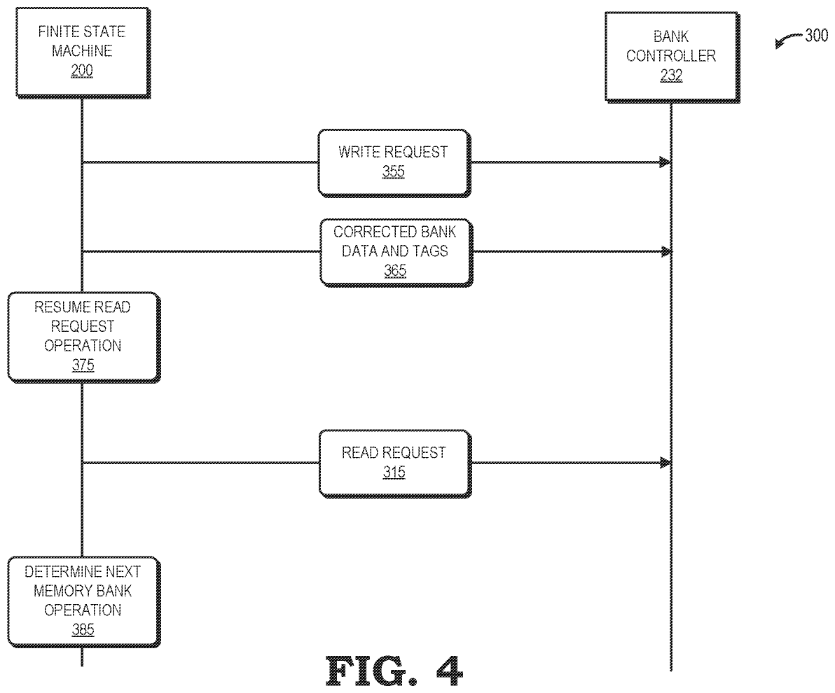

Referring now to FIGS. 3 and 4, FIGS. 3 and 4 together present an example operation 300 for SRAM scrubbing is presented, in accordance with some embodiments. According to embodiments, example operation 300 is implemented, at least in part, by finite state machine 200 and a bank controller 232. Referring now to FIG. 3, in embodiments, example operation 300 includes finite state machine 200 generating a scrub request 305 that includes data indicating that SRAM scrubbing is to begin for a memory bank (e.g., critical memory bank 116, non-critical memory bank 118, shared memory bank 120) of SRAM 114. After generating the scrub request 305, finite state machine 200 (e.g., via memory arbiter 122, memory scrubbing circuitry 124) provides the scrub request 305 to a bank controller 232 associated with the memory bank indicated in the scrub request 305. In response to receiving the scrub request 305, the bank controller 232 blocks read and write access to the memory bank indicated in the scrub request 305 by one or more components in critical domain 105, non-critical domain 115, or both. For example, the bank controller 232 blocks all read and write access to the memory bank by components in critical domain 105 and non-critical domain 115 such that only finite state machine 200 has access to the memory bank while the memory bank is scrubbed. Further, example operation 300 includes finite state machine 200 generating a read request 315 including data indicating the memory bank and providing the read request to bank controller 232. Based on receiving the read request 226, the bank controller 232 begins to read out data and tags (represented in FIG. 3 as bank data and tags 325) from the memory bank indicated in the read request 226. The bank controller 232 then provides the bank data and tags 325 to finite state machine 200.

Based on receiving bank data and tags 325, finite state machine 200 begins error correction operation 335. Error correction operation 335, for example, includes finite state machine 200 implementing one or more ECCs 205 configured to detect one or more single-bit memory errors, multi-bit memory errors, or both in bank data and tags 325. In embodiments, example operation 300 includes finite state machine 200 detecting one or more single-bit memory errors, multi-bit memory errors, or both in bank data and tags 325 during error correction operation 335. In response to detecting one or more single-bit memory errors, multi-bit memory errors, or both in bank data and tags 325 during error correction operation 335, finite state machine 200 is configured to correct the detected single-bit and multi-bit memory errors in bank data and tags 325 based on the ECCs 205 being implemented by the finite state machine 200 to produce corrected bank and data tags 365. After correcting the detected single-bit and multi-bit memory errors in bank data and tags 325 to produce corrected bank and data tags 365, finite state machine 200 performs disable read operation 345. During disable read operation 345, finite state machine 200 suspends read request 315 and stops reading bank data and tags 325.

Referring now to FIG. 4, after suspending read request 315, finite state machine 200 generates a write request 355 that includes data indicating the memory bank and data representing corrected bank data and tags 365. Once write request 355 has been generated, finite state machine 200 provides the write request 355 to bank controller 232. Based on the write request 355, the bank controller 232 writes the corrected bank data and tags 365 to the memory bank. According to embodiments, once finite state machine 200 sends provides write request 355, finite state machine 200 performs resume read operation 375. During resume read operation 375, finite state machine 200 resumes reading bank data and tags 325 by, for example, resuming read request 315. As an example, finite state machine 200 resumes reading the bank data and tags 325 read out by bank controller 232, sends read request 315 again to bank controller 232, or both. Once finite state machine 200 has completed checking the data of a memory bank, finite state machine 200 performs determine next memory bank operation 385. That is to say, once finite state machine 200 has checked each bit of bank data and tags 325 and found no single-bit or multi-bit memory errors, finite state machine 200 performs determine next memory bank operation 385. During determine next memory bank operation 385, finite state machine 200 identifies a next memory bank to check for memory errors by determining whether or not a redirect request 235 has been received. Based on no redirect request 235 having been received by finite state machine 200, finite state machine 200 begins checking a next sequential memory bank in SRAM 114 (e.g., as indicated by one or more memory addresses associated with SRAM 114) for memory errors after an event trigger 225 occurs. Based on a redirect requests 235 having been received by finite state machine 200, finite state machine 200 begins checking the memory bank in SRAM 114 identified in the received redirect request 235 for memory errors.

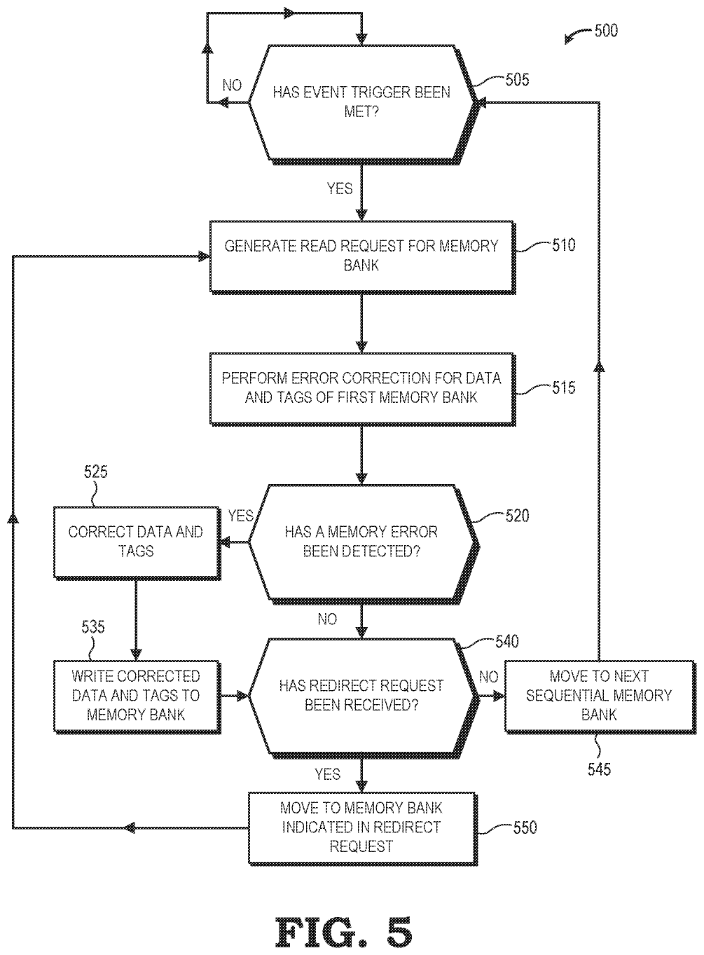

Referring now to FIG. 5, an example method 500 for SRAM scrubbing is presented. In embodiments, example method 500 is implemented by finite state machine 200. At block 505 of example method 500, finite state machine 200 determines if one or more certain event triggers 225 have occurred. As an example, finite state machine 200 determines whether a predetermined amount of time has elapsed. Based on the one or more certain event triggers 225 not having yet occurred, finite state machine waits at block 505. Based on the one or more certain event triggers 225 having occurred, finite state machine generates a read request (e.g., read request 315) at block 510. The read request, for example, includes data requesting data to be read out and data identifying a first memory bank (e.g., critical memory bank 116, non-critical memory bank 118, shared memory bank 120) of SRAM 114. After generating the read request, at block 510, finite state machine 200 provides the read request to a bank controller 232 associated with the first memory bank of SRAM 114. At block 515, finite state machine 200 receives the data and tags of the first memory bank read out by the bank controller 232. Finite state machine 200 then implements one or more ECCs 205 so as to check the data and tags of the first memory bank for one or more single-bit memory errors, multi-bit memory errors, or both. At block 520, finite state machine 200 determines whether one or more ECCs 205 have detected one or more single-bit memory errors, multi-bit memory errors, or both. Based on finite state machine 200 determining one or more single-bit memory errors or multi-bit memory errors have been detected, at block 525, finite state machine 200 corrects the memory errors in the data and tags of the first memory bank based on the implemented ECCs 205. For example, finite state machine 200 corrects the memory errors in the data and tags of the first memory bank to produce a set of corrected data and tags (e.g., corrected bank data and tags 365). At block 535, finite state machine 200 then generates a write request (e.g., write request 355) that includes data indicating the first memory bank of the SRAM 114 and data representing the corrected data and tags. Finite state machine 200 then provides the write request to the bank controller 232 associated with the first memory bank such that the corrected data and tags are written to the first memory bank. Finite state machine 200 then moves to block 540.

Referring again to block 520, based on finite state machine 200 not determining one or more single-bit memory errors or multi-bit memory errors have been detected, at block 540, finite state machine 200 determines if a redirect request 235 has been received by the finite state machine 200. Based on no redirect request having been received, finite state machine 200, at block 545, begins to check for memory errors in a next sequential memory bank in SRAM 114 (e.g., as indicated by one or more memory addresses associated with SRAM 114). Finite state machine 200 then waits, at block 505, for the event trigger 225 to again occur before checking the next sequential memory bank for memory errors. After the event trigger 225 occurs again, at block 510, finite state machine 200 generates a read request identifying the next sequential memory bank moved to at block 545. Referring again to block 540, based on a redirect request 235 having been received, finite state machine 200, at block 550, begins to check for memory errors in the memory bank identified in the received redirect request 235. Finite state machine 200 then waits, at block 505, for the event trigger 225 to again occur before checking the memory bank identified in the received redirect request 235 for memory errors. Once the event trigger 225 occurs again, at block 510, finite state machine 200 generates a read request identifying the memory bank identified in the received redirect request 235.

In some embodiments, the apparatus and techniques described above are implemented in a system including one or more integrated circuit (IC) devices (also referred to as integrated circuit packages or microchips), such as the SOC described above with reference to FIGS. 1-6. Electronic design automation (EDA) and computer-aided design (CAD) software tools may be used in the design and fabrication of these IC devices. These design tools typically are represented as one or more software programs. The one or more software programs include code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer-readable storage medium accessible to the computing system. Likewise, the code representative of one or more phases of the design or fabrication of an IC device may be stored in and accessed from the same computer-readable storage medium or a different computer-readable storage medium.

A computer-readable storage medium may include any non-transitory storage medium, or combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer-readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

In some embodiments, certain aspects of the techniques described above may be implemented by one or more processors of a processing system executing software. The software includes one or more sets of executable instructions stored or otherwise tangibly embodied on a non-transitory computer-readable storage medium. The software can include the instructions and certain data that, when executed by the one or more processors, manipulate the one or more processors to perform one or more aspects of the techniques described above. The non-transitory computer-readable storage medium can include, for example, a magnetic or optical disk storage device, solid-state storage devices such as Flash memory, a cache, random access memory (RAM), or other non-volatile memory device or devices, and the like. The executable instructions stored on the non-transitory computer-readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

1. A processing system comprising:
a random-access memory (RAM) shared between a first domain and a second domain of a system on a chip (SOC), the first domain including a first set of components of the SOC and the second domain including a second set of components of the SOC; and
a finite state machine configured to check a first bank of the RAM for one or more memory errors concurrently with read and write access to the first bank of the RAM being disabled for the first set of components of the first domain and the second set of components of the second domain.

2. The processing system of claim 1, wherein the finite state machine is configured to check the first bank of the RAM for one or more errors by implementing an error correction code.

3. The processing system of claim 1, wherein the first domain is powered by a first power rail and the second domain is powered by a second power rail that is different from the first power rail.

4. The processing system of claim 1, wherein the finite state machine is configured to:
check a second bank of the RAM based on a predetermined time interval elapsing after the finite state machine has checked the first bank of the RAM for one or more memory errors, wherein the second bank is a next sequential memory bank of the RAM as indicated by a memory address associated with the RAM.

5. The processing system of claim 1, wherein the finite state machine is configured to:
concurrently with checking the first bank of the RAM for one or more memory errors, receive a redirect request indicating a memory error in a second bank of the RAM; and
in response to receiving the redirect request, check the second bank of the RAM for one or more errors.

6. The processing system of claim 1, wherein the finite state machine is configured to: based on detecting a multi-bit memory error in the first bank, generate an interrupt.

7. The processing system of claim 1, wherein the finite state machine is configured to:
concurrently with read and write access to a first bank of the RAM being disabled for the first set of components of the first domain and the second set of components of the second domain and in response to detecting a single-bit memory error in the first bank, write corrected data into the first bank.

8. The processing system of claim 7, wherein the finite state machine is configured to:
provide, to a memory controller, a request indicating that read and write access to the first bank of the RAM is to be disabled based on a predetermined period of time elapsing.

9. A method, comprising:
reading, by a finite state machine, data from a first bank of a random-access memory (RAM) shared between a first domain and a second domain of a system on a chip (SOC) concurrently with read and write access to the first bank of the RAM being disabled for one or more components of the first domain of the SOC and one or more components of the second domain of the SOC; and
checking, at the finite state machine, the data from the first bank for one or more memory errors.

10. The method of claim 9, wherein checking the data from the first bank for one or more memory errors includes implementing an error correction code.

11. The method of claim 9, wherein the first domain is powered by a first power rail and the second domain is powered by a second power rail that is different from the first power rail.

12. The method of claim 9, further comprising:
checking a second bank of the RAM for one or more memory errors based on a predetermined time interval elapsing after the finite state machine has checked the first bank of the RAM for one or more memory errors, wherein the second bank is a next sequential memory bank of the RAM as indicated by a memory address associated with the RAM.

13. The method of claim 9, further comprising:
concurrently with checking the first bank of the RAM for one or more memory errors, receiving, at the finite state machine, a redirect request indicating a memory error in a second bank of the RAM; and
in response to receiving the redirect request, checking a second bank of the RAM for one or more errors.

14. The method of claim 9, further comprising:
based on detecting a multi-bit memory error in the first bank, generating an interrupt.

15. The method of claim 9, further comprising:
concurrently with read and write access to a first bank of the RAM being disabled for the one or more components of the first domain and the one or more components of the second domain and in response to detecting a single-bit memory error in the first bank, writing corrected data into the first bank.

16. The method of claim 15, further comprising:
providing, to a memory controller, a request indicating that read and write access to the first bank of the RAM is to be disabled based on a predetermined period of time elapsing.

17. A system comprising:
a non-critical domain comprising a central processing unit;
a critical domain powered independently from the non-critical domain;
a random access memory (RAM) shared between the non-critical domain and the critical domain, the RAM including a plurality of banks; and
a finite state machine configured to:
sequentially check each bank of the plurality of banks for one or more memory errors.

18. The system of claim 17, wherein the finite state machine is configured to wait a predetermined time interval after checking each bank of the plurality of banks for one or more memory errors.

19. The system of claim 17, wherein a first subset of the plurality of banks is assigned to the critical domain and a second subset of the plurality of banks is assigned to the non-critical domain.

20. The system of claim 17, wherein the finite state machine is configured to, based on detecting a memory error in a bank of the plurality of banks, write corrected data to the bank, wherein write access to the bank is blocked for components of the critical domain.
